(19) United States
(12) Patent Application Publication
(10) Pub. No.: US 2019/0028806 A1
(43) Pub. Date: Jan. 24, 2019

(54) Amplifier with Voice Activated Audio Override

(71) Applicants: Jeremy Burkhard, Riverside, CA (US); Joseph Whitaker, Riverside, CA (US)

(72) Inventors: Jeremy Burkhard, Riverside, CA (US); Joseph Whitaker, Riverside, CA (US)

(73) Assignee: Origin Acoustics, LLC, Las Vegas, NV (US)

(21) Appl. No.: 16/035,951

(22) Filed: Jul. 16, 2018

Related U.S. Application Data
(60) Provisional application No. 62/534,380, filed on Jul. 19, 2017.

(51) Int. Cl. H04R 5/04; H03F 3/68; G10L 15/22

(52) U.S. Cl. CPC H04R 5/04; H03F 3/68; H04W 4/80; G10L 2015/221; G10L 2015/223; G10L 15/22

(57) ABSTRACT

An amplifier with voice activated audio override is disclosed. The amplifier with voice activated audio override mutes the audio signal from audio output devices that do not contain integrated hardware to mute the audio level under certain conditions. The amplifier can be hardwired or temporally wired to the audio system. The hard wiring can be by cutting and splicing the audio wiring or can be wired upon installation. The temporal wiring can be with jacks, connectors or other mechanisms. The muting can be adjustable depending upon different conditions. The variable muting can be a percentage or decibels of the audio signal or can be a fixed sound or decibel level regardless of the present volume or decibel level. The amplifier with can be parasitically powered from the audio device, sound system or from a separate power source.

### CROSS REFERENCE TO RELATED APPLICATIONS

This application claims the benefit of Provisional Application Ser. No. 62/534,380 filed Jul. 19, 2017 the entire contents of which is hereby expressly incorporated by reference herein.

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC

Not Applicable

### BACKGROUND OF THE INVENTION

### Field of the Invention

This invention relates to improvements in an amplifier with voice activated audio override. More particularly, the present wired amplifier with voice activated audio override connects to an audio sound system and reduces the audio sound when a user is verbally communicating with the system.

### Description of Related Art Including Information Disclosed Under 37 CFR 1.97 and 1.98

A number of communications systems that allow a person to talk to a device, and have the device communicate with the internet and then answer are becoming more common. These devices are also used to play or stream the same or different music continuously to one or a multiple of locations. When communicating with these devices there is a need to reduce the sound level when a person is talking, or the system is replying to the user. Some system may reduce the audio level by themselves, but other systems are separate from the communications and are not aware that the verbal communication is taking place.

A number of patents and or publications have been made to address these issues. Exemplary examples of patents and or publication that try to address this/these problem(s) are identified and discussed below.

U.S. Pat. No. 8,428,758 issued on Apr. 23, 2013 to Devang Kalidas Naik et al., is titled Dynamic Audio Ducking. This patent discloses a primary audio stream that may include music and a secondary audio stream may include a voice announcement of one or more pieces of information pertaining to the primary audio stream, such as the name of the track or the name of the artist. Each audio stream is played at a different loudness or one audio stream is muted when both audio streams are played together. While there can be multiple loudness levels for the different or combined audio streams, the separate audio streams are mixed from a codec.

U.S. Pat. No. 9,654,076 issued on May 16, 2017 to Tomlinson M. Holman et at., is titled Metadata for Ducking Control. This patent discloses an audio encoding device and an audio decoding device are described herein. The audio encoding device may examine a set of audio channels/channel groups representing a piece of sound program content and produce a set of ducking values to associate with one of the channels/channel groups. During playback of the piece of sound program content, the ducking values may be applied to all other channels/channel groups. In this patent the data is encoded with loudness levels and the playback device reads the loudness level to determine the playback loudness or ducking. It does not dynamically determine the ducking level without the metadata.

U.S. Pat. No. 9,219,973 that issued on Dec. 22, 2015 and US publication 2016/0071527 that was published on Mar. 10, 2016, both to Hannes Muesch are titled Method and System for Scaling Ducking of Speech-Relevant Channels in Multi-Channel Audio. They disclose a method and system for filtering a multi-channel audio signal having a speech channel and at least one non-speech channel, to improve intelligibility of speech determined by the signal. In typical embodiments, the method includes steps of determining at least one attenuation control value indicative of a measure of similarity between speech-related content determined by the speech channel and speech-related content determined by the non-speech channel and attenuating the non-speech channel in response to the at least one attenuation control value. These references also use multiple channels where the different audio channels enter the gain from different sources.

What is needed is an amplifier with voice activated audio override that is separate from the source and can detect when certain audio sounds should be muted, while leaving other audio content at a default audio loudness. The proposed voice activated audio override system provides a solution with a separate device that can be wired between an audio output and a sound producing device.

### BRIEF SUMMARY OF THE INVENTION

It is an object of the amplifier with voice activated audio override to mute the audio signal from audio output devices that do not contain integrated hardware to mute the audio level under certain conditions. Many audio amplifier systems simply play or reproduce audio signals regardless of sounds that are being made near the audio system. The voice activated audio override system intercepts the audio signal and is able to mute or suspend the signal when and as needed to allow for verbal commands, feedback or other conditions to complete before restoring or continuing previous audio sound levels.

It is an object of the amplifier with voice activated audio override to be hardwired or temporally wired to the audio system. The hard wiring can be by cutting and splicing the audio wiring or can be wired upon installation. The temporal wiring can be with RCA jacks, phone jacks, mini phone jacks, firewire, RJ45, USB, mobile communication connectors or others. These wiring connections have direct control over the audio signal between the audio signal output device and the speaker, amplifier that drives a speaker or other system.

It is another object of the amplifier with voice activated audio override to have variable control over the muting or ducking of the audio signal. The variable muting can be adjustable depending upon different conditions. As an example, communication regarding emergency conditions may have a higher amount of muting as opposed to a notification that a phone message has been received. The variable amount of muting can be a percentage or decibels of the audio signal or can be a fixed sound or decibel level regardless of the present volume or decibel level.

It is still another object of the amplifier with voice activated audio override to be parasitically powered from the audio device, sound system or for the voice activated audio override system to be powered by a separate power source. The audio ducking system can further be configured with a plurality of connectors or adapters to handle a variety of power sources without requiring a different audio ducking system depending upon the input and output devices.

Various objects, features, aspects, and advantages of the present voice activated audio override will become more apparent from the following detailed description of preferred embodiments of the invention, along with the accompanying drawings in which like numerals represent like components.

### BRIEF DESCRIPTION OF THE SEVERAL VIEWS OF THE DRAWING(S)

FIG. 1 shows an amplifier with voice activated audio override.

FIG. 2 shows a contemplated example of a balun transformer device with connections.

FIG. 3 shows a block diagram of operation.

### DETAILED DESCRIPTION OF THE INVENTION

It will be readily understood that the components of the present invention, as generally described and illustrated in the drawings herein, could be arranged and designed in a wide variety of different configurations. Thus, the following more detailed description of the embodiments of the system and method of the present invention, as represented in the drawings, is not intended to limit the scope of the invention but is merely representative of various embodiments of the invention. The illustrated embodiments of the invention will be best understood by reference to the drawings, wherein like parts are designated by like numerals throughout.

### ITEM NUMBERS AND DESCRIPTION

18 audio source
19 power source
20 multichannel voice activated audio override
21 module
22 RJ45 connector jack
23 phone jack
30 balun transformer
31 zone
32 balun transformer
33 zone
34 balun transformer
35 zone
40 wired connection
42 wired connection
44 wired connection
50 balun transformer
52 balun transformer
54 balun transformer
60 wired
62 wired
64 wired
70 speaker
72 speaker
74 speaker
80 microphone
82 microphone
84 microphone
90 audio content
91 spoken command
92 no command is detected
93 public service announcement
94 audio content
95 application
96 Internet
97 restore audio content

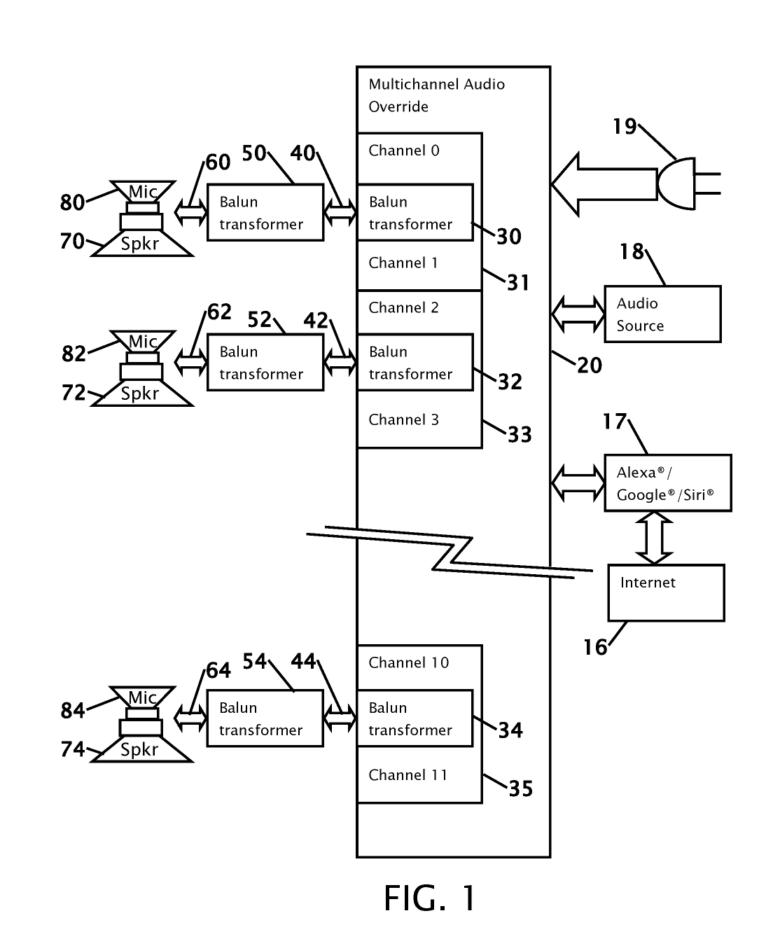

FIG. 1 shows a block diagram of the amplifier with voice activated audio override. In this embodiment, the amplifier connects to a multichannel voice activated audio override (VAAO) 20. The voice activated audio override is striped out an existing audio and plays Alexa or Google home voice then return the previous audio original source content to the speakers. This allows a person to interact with the Alexa or Google home voice without the audio track interfering with detecting the speech recognition as a person both talks and listens to the Alexa or Google home voice or similar services. In some cases, the audio is suspended and not muted. Suspension of audio content is useful when the audio content is instructions, a book or story.

In this figure, the multichannel voice activated audio override (VAAO) 20 is a 12-channel device with 6 zones 31, 33 . . . 35. There are three independent multichannel voice activated audio override (VAAO) output/inputs that are connected to balun 30, 33 . . . 35 or similar isolation transformers that are integrated connected or otherwise electrically connected to the zones. The term balun is derived by combining balanced and unbalanced. The balun transformers 30, 32 . . . 34 are connected with wired connections 40, 42 . . . 44 to balun transformers 50, 52 . . . 54 that are wired 60, 62 . . . 64 to speakers 70, 72 . . . 74 and/or microphones 80, 82 . . . 84. The baluns isolate a transmission line and provide a balanced output. A typical use for a balun is in a television antenna. The term is derived by combining balanced and unbalanced. The baluns are used to convert an unbalanced signal to a balanced one or vice versa. While a wired connection 40, 42 . . . 44 is shown and described between the balun transformers, it should be understood that a wireless connection between the multichannel voice-activated audio override (VAAO) 20 and the speakers/microphones.

Using a wireless connection will require multiple wireless transmission and receiving channels/frequencies and power supplies with amplifiers. While the preferred embodiment is with wired connection, it is within the contemplated ability of one skilled in the art to use Wi-Fi, Bluetooth, RF, IR, radio waves, cellular or other technology. It is further contemplated that only one or more channel could utilize wireless communication where hardwired connection is impractical or less desirable.

In the preferred embodiment the speakers 70, 72 . . . 74 are driven with a 50-watt RMS/Channel amplifier (not shown). While a particular output level is identified in the preferred embodiment, the power level of the amplifier is selected or sized based upon the environment and user requirements/design. The multichannel voice activated audio override (VAAO) 20 is connected to a power source 19, and an audio source 18. The audio source 18 provides audio content and can be from a CD, flash drive, TV, mobile device (such as a cell phone) or other audio device. The multichannel voice activated audio override (VAAO) 20 further is connected to the internet 16 or other device through an application connected device such as, but not limited to Alexa®, Google® or Siri® 17.

While this figure shows and discloses a voice activated audio override 20 with 12-channels, it is contemplated that a voice activated audio override 20 with more or less than 12-channels is contemplated and can be adjusted based upon technology and installation requirements. The voice activated audio override 20 is optimized for customers for use as an integrator, builder market and conference rooms.

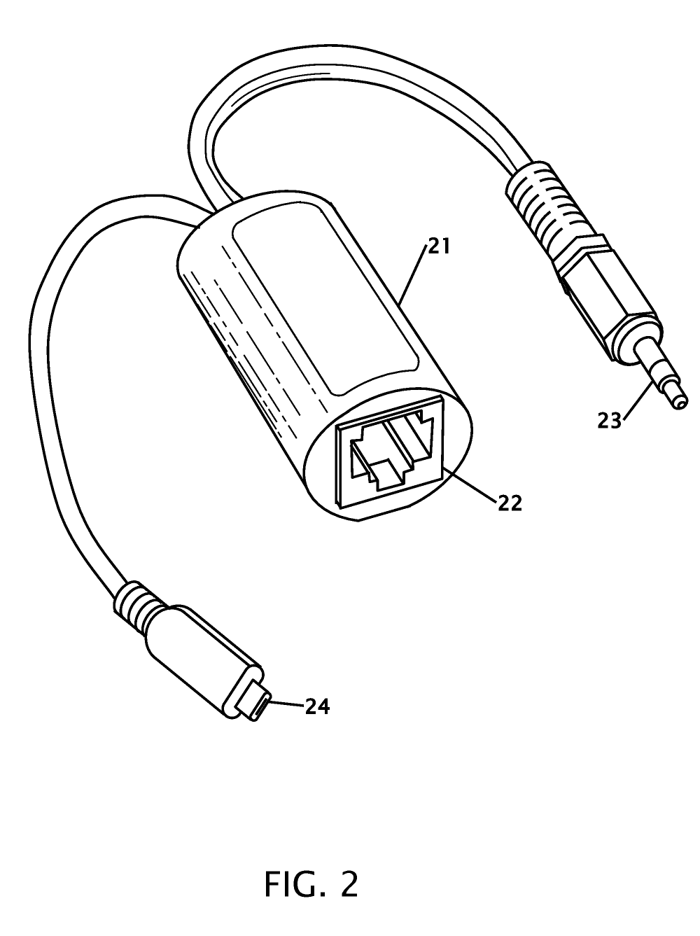

FIG. 2 shows a contemplated example of a balun transformer device with connections. The module 21 includes a balun transformer with a connector 22 that is integrated into the module 21. In the preferred embodiment, the module is powered with a 12 volt, but could also have a 5 volt or operate on a selectable 5 or 12-volt supply.

The connector 22, in the embodiment shown is a RJ45 jack 22 for balun in/out on zones 1-3 and input and output control. The balun is shown with a 3.5 mm stereo phone jack 23. The balun also has at least a second connector with a mini Universal Serial Buss (USB) jack 24 that supplies the power. While a particular set of connectors is shown and described, nearly any from or style of connectors.

For the RJ45 22 and RJ11, (High-Definition Multimedia Interface (HDMI). For the 3.5 mm phone jack could a pair of 3.5 mm mono phone jacks, Radio Corporation of America (RCA) jacks or stripped wires. For the mini USB a USB, USBA, USBB, USBC, firewire, stripped wire, and standard tip/ring power connector or other connector(s) is contemplated. The module can have an automatic On and Off circuit to power the module 21. The off or sleep mode can operate at a 1 u or less power consumption.

The voice activated audio override has internal protection and a pink noise generator. The voice activated audio override is controlled by an application where it can be adjusted. The application can be re-skinned for OA use.

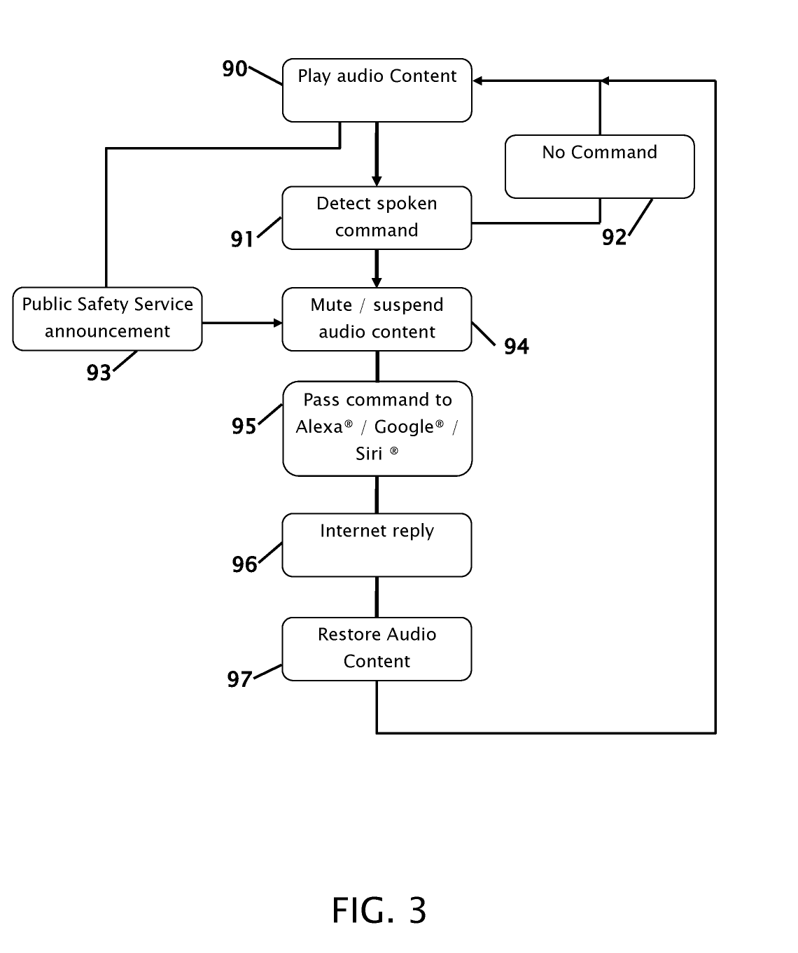

FIG. 3 shows a block diagram of operation. The interface with the voice activated audio override is with a Sony/Phillips Digital Interface (SPDIF) input. The SPDIF, also written as S/PDIF is an interface to transmit digital audio. Digital audio means that the audio signal is transmitted encoded in a series of 0s and 1s instead of being transmitted in analog format. This makes audio have higher fidelity, because no noise will be added to the audio signal. Therefore, it is always better to transmit audio in digital format. There are two consumer-level interfaces to transmit audio in digital format: SPDIF and HDMI (High-Definition Multimedia Interface). SPDIF transmits only audio, but HMDI also carries digital video signal.

Under normal operation the voice activated audio override will play the audio content 90. With the multiple channels the same or different audio content can be played at each location. If a microphone detects sounds or speech, Alexa (or other device) will determine if a spoken command 91 is detected. If no command is detected 92 the audio content will continue to play. Upon detection, the voice activated audio override will mute or suspend the audio content 94. In some cases, the muting will continue to play the audio content 94 at a lower or muted volume level. In other cases, the system will pause or suspend playing the audio content 94. Any detected command will be passed to the detection and analytical module or application 95 such as, but not limited to Alexa®, Google®, Siri®.

The application 95 passes the instruction to the internet 96 for a reply. There may be one or more spoken commands from the user and replies from the analytical module or application. The interactions can be local to a single room or in some cases communicated to all connected nodes in the voice activated audio override device. Once the communication is complete, the voice activated audio override will restore audio content 97. In another contemplated uses a public safety service announcement 93 can be used to mute the voice activated audio override without a spoken command. The audio content can be muted or suspended while the public service announcement 93 is in process and continues after the public service announcement 93 has concluded. The announcement can be sent to just one zone, to selected zones or to all zones.

Thus, specific embodiments of an amplifier with voice activated audio override has been disclosed. It should be apparent, however, to those skilled in the art that many more modifications besides those described are possible without departing from the inventive concepts herein. The inventive subject matter, therefore, is not to be restricted except in the spirit of the appended claims.

### SEQUENCE LISTING

Not Applicable.

1. An amplifier with voice activated audio override comprising:
an amplifier:
said amplifier includes a voice activated audio override which allows a voice interface transaction to override currently sourced audio content and replace said voice interface with voice responses of a voice interface, and
said voice activated audio override further allows for an interrupted sourced audio content to return upon completion of said voice interface transaction.

2. The amplifier with voice activated audio override according to claim 1, wherein said amplifier has an output that provides power to a remote voice interface and returns said sourced audio content from said voice interface to said amplifier.

3. The amplifier with voice activated audio override according to claim 1, wherein said amplifier includes at least one pair of balun transformers that both feeds power to said voice interface transaction and feeds audio content to said amplifier.

4. The amplifier with voice activated audio override according to claim 3, wherein said amplifier and said at least one pair of balun transformers are connected with data cables with terminations.

5. The amplifier with voice activated audio override according to claim 1, wherein said balun is connected to a multichannel voice activated audio override (VAAO) output/inputs.

6. The amplifier with voice activated audio override according to claim 5, wherein said multichannel voice activated audio override (VAAO) includes at least four channels.

7. The amplifier with voice activated audio override according to claim 6, wherein said at least four channels operates at least two zones.

8. The amplifier with voice activated audio override according to claim 7, wherein each of said at least two zones include one output and one input channel.

9. The amplifier with voice activated audio override according to claim 1, wherein said amplifier has dual input attenuation that balance audio input levels between said voice activated audio override and localized source content to an amplified output.

10. The amplifier with voice activated audio override according to claim 9, wherein said amplified output is to at least one zone to provide incoming source leveling with said voice interface in said at least one zone.

11. The amplifier with voice activated audio override according to claim 1, wherein said voice activated audio override detects verbal command from at least one of Alexa®, Google® and Siri®.

12. The amplifier with voice activated audio override according to claim 1, wherein said amplifier is wired to a connection with at least one of a group consisting of an RJ45 connector, an RJ11 connector, a 3.5 mm phone jack, a Radio Corporation of America (RCA)® jack, stripped wires, mini USB, USB, USBA, USBB, USBC, firewire and a tip/ring power connector.

13. The amplifier with voice activated audio override according to claim 1, wherein said amplifier is connected with a wireless connection from a group consisting of Wi-Fi, Bluetooth, RF, IR, radio waves and cellular technology.

14. The amplifier with voice activated audio override according to claim 13, wherein said wireless connection uses more than one wireless transmission and receiving channels/frequencies.

15. The amplifier with voice activated audio override according to claim 1, wherein said override currently sourced audio content connects to an audio sound system and reduces said currently sourced audio content sound when a user is verbally communicating.

16. The amplifier with voice activated audio override according to claim 1, wherein said amplifier is separate from said currently sourced audio content and detects when at least one audio sound should be muted, while leaving other audio content at a default audio loudness.

17. The amplifier with voice activated audio override according to claim 1, wherein said muting is a percentage or number of decibels of said currently sourced audio content.

18. The amplifier with voice activated audio override according to claim 1, wherein said muting is a fixed sound or a finite decibel level regardless of the present volume or decibel level.

19. The amplifier with voice activated audio override according to claim 1, wherein said amplifier is parasitically powered from an audio device that produces said currently sourced audio content or from a separate power source.
